(19) United States
(12) Patent Application Publication
(10) Pub. No.: US 2026/0090115 A1
(43) Pub. Date: Mar. 26, 2026

(54) PHOTONIC CHIPS INCLUDING A HYBRID PLASMONIC PHOTODETECTOR

(71) Applicant: GlobalFoundries U.S. Inc., Malta, NY (US)

(72) Inventor: Yusheng Bian, Ballston Lake, NY (US)

(21) Appl. No.: 18/895,545

(22) Filed: Sep. 25, 2024

(51) Int. Cl. H01L 31/105; G02B 6/122; H01L 31/18

(52) U.S. Cl. CPC H10F 30/223; G02B 6/1228; H10F 71/1212

(57) ABSTRACT

Structures for a photonic chip that include a photodetector and methods of forming such structures. The structure comprises a photodetector including a pad, a semiconductor layer on the pad, and a metal layer that extends into the pad. The semiconductor layer may be configured to absorb light of a given wavelength.

### BACKGROUND

This disclosure relates to photonic chips and, more specifically, to structures for a photonic chip that include a photodetector and methods of forming such structures.

Photonic chips are used in many applications and systems including, but not limited to, data communication systems and data computation systems. A photonic chip includes a photonic integrated circuit comprised of photonic components, such as modulators, polarizers, and couplers, that are used to manipulate light received from a light source, such as an optical fiber or a laser. A photodetector may be employed in the photonic integrated circuit to convert light, which may be modulated as an optical signal, into an electrical signal.

Improved structures for a photonic chip that include a photodetector and methods of forming such structures are needed.

### SUMMARY

In an embodiment of the invention, a structure for a photonic chip is provided. The structure comprises a photodetector including a pad, a semiconductor layer on the pad, and a metal layer that extends into the pad. The semiconductor layer is configured to absorb light of a given wavelength.

In an embodiment of the invention, a method of forming a structure for a photonic chip is provided. The method comprises forming a pad of a photodetector, forming a semiconductor layer on the pad, and forming a metal layer that extends into the pad. The semiconductor layer is configured to absorb light of a given wavelength.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 1A is a cross-sectional view taken generally along line 1A-1A in FIG. 1.

FIG. 2 is a top view of the structure at a fabrication stage of the processing method subsequent to FIGS. 1, 1A.

FIG. 2A is a cross-sectional view taken generally along line 2A-2A in FIG. 2.

FIG. 3 is a cross-sectional view of a structure in accordance with embodiments of the invention.

FIG. 4 is a cross-sectional view of a structure in accordance with embodiments of the invention.

FIG. 5 is a top view of a structure in accordance with alternative embodiments of the invention.

FIG. 6 is a top view of a structure in accordance with alternative embodiments of the invention.

FIG. 7 is a top view of a structure in accordance with alternative embodiments of the invention.

FIG. 8 is a cross-sectional view of a structure in accordance with alternative embodiments of the invention.

FIG. 8A is a cross-sectional view of a structure in accordance with alternative embodiments of the invention.

FIG. 9 is a top view of a structure in accordance with alternative embodiments of the invention.

### DETAILED DESCRIPTION

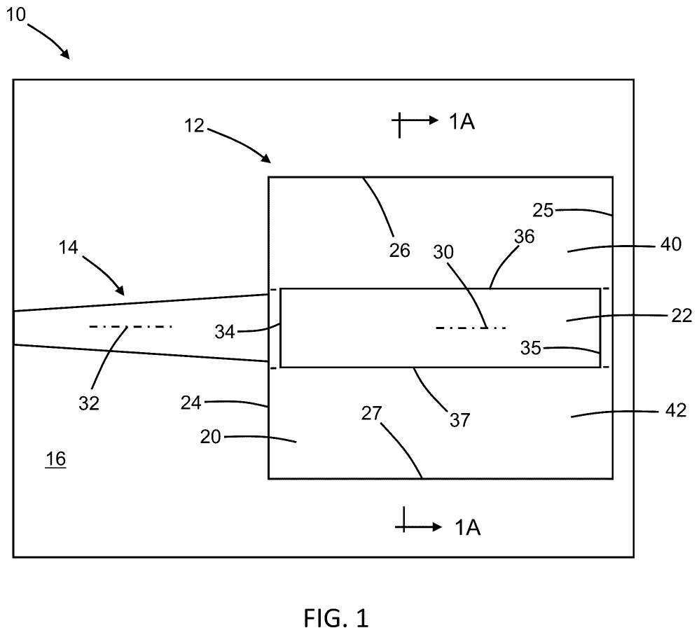

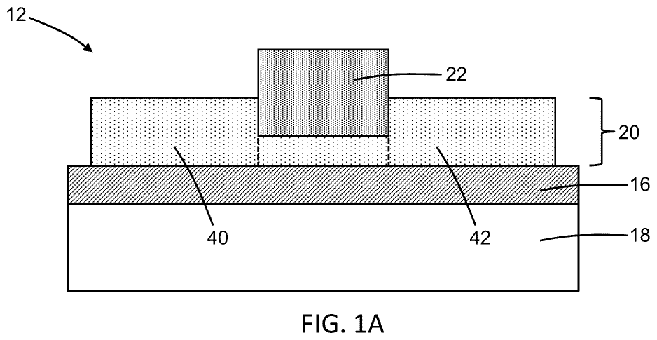

With reference to FIGS. 1, 1A and in accordance with embodiments of the invention, a structure 10 for a photonic chip includes a photodetector 12 and a waveguide core 14 that is coupled to the photodetector 12. The photodetector 12 and the waveguide core 14 are positioned on, and above, a dielectric layer 16 and a semiconductor substrate 18. In an embodiment, the dielectric layer 16 may be comprised of a dielectric material, such as silicon dioxide, and the semiconductor substrate 18 may be comprised of a semiconductor material, such as single-crystal silicon. In an embodiment, the dielectric layer 16 may be a buried oxide layer of a silicon-on-insulator substrate. The dielectric layer 16 may provide low-index and electrically-insulating cladding that separates the photodetector 12 and the waveguide core 14 from the semiconductor substrate 18.

The photodetector 12 includes a pad 20 and a semiconductor layer 22 providing a light-absorbing layer that is disposed on the pad 20. The pad 20 has a side edge 24, a side edge 25 opposite from the side edge 24, a side edge 26, and a side edge 27 opposite from the side edge 26. The side edges 24, 25, 26, 27, which may surround a perimeter of the pad 20, may extend from a top surface of the pad 20 to a top surface of the dielectric layer 16.

The semiconductor layer 22 of the photodetector 12 provides a light-absorbing layer that is disposed on the pad 20 with an inward spacing from the outer perimeter of the pad 20. The semiconductor layer 22 may have a perimeter surrounded by a sidewall 34, a sidewall 35 opposite from the sidewall 34, a sidewall 36, and a sidewall 37 opposite from the sidewall 36. The sidewall 34 is positioned adjacent to the side edge 24 of the pad 20, the sidewall 35 is positioned adjacent to the side edge 25 of the pad 20, the sidewall 36 is positioned adjacent to the side edge 26 of the pad 20, and the sidewall 37 is positioned adjacent to the side edge 27 of the pad 20. The semiconductor layer 22 extends lengthwise along a longitudinal axis 30 from the sidewall 34 to the sidewall 35. A portion of the pad 20 is laterally positioned between the sidewall 36 of the semiconductor layer 22 and the side edge 26 of the pad 20. Another portion of the pad 20 is laterally positioned between the sidewall 37 of the semiconductor layer 22 and the side edge 27 of the pad 20.

The waveguide core 14 may include a tapered portion that adjoins the side edge 24 of the pad 20 adjacent to the sidewall 34 of the semiconductor layer 22. The tapered portion of the waveguide core 14 adjoining the side edge 24 may have a width dimension that increases with decreasing distance from the side edge 24 of the pad 20. In an embodiment, the width dimension of the tapered portion of the waveguide core 14 adjoining the pad 20 may increase linearly with decreasing distance from the side edge 24. In an alternative embodiment, the width dimension of the tapered portion of the waveguide core 14 adjoining the pad 20 may vary based on a non-linear function, such as a quadratic function, a cubic function, a parabolic function, a sine function, a cosine function, a Bezier function, or an exponential function. In an embodiment, the tapered portion of the waveguide core 14 adjoining the pad 20 may include a single stage of tapering characterized by a taper angle. In an alternative embodiment, the tapered portion of the waveguide core 14 adjoining the pad 20 may taper in multiple stages each characterized by a different taper angle.

In an alternative embodiment, the structure 10 may include another waveguide core having a tapered portion that adjoins the side edge 25 of the pad 20, and the semiconductor layer 22 may be positioned between the tapered portion of the added waveguide core adjoining the side edge 25 and the tapered portion of the waveguide core 14 adjoining the side edge 24. An optical splitter may be configured to split the optical power delivered to the photodetector 12 by the added waveguide core and the waveguide core 14.

In an embodiment, the waveguide core 14 and the pad 20 of the photodetector 12 may be comprised of a material having a refractive index that is greater than the refractive index of silicon dioxide. In an embodiment, the waveguide core 14 and the pad 20 of the photodetector 12 may be comprised of a semiconductor material. In an embodiment, the waveguide core 14 and the pad 20 of the photodetector 12 may be comprised of single-crystal silicon. The waveguide core 14 and the pad 20 of the photodetector 12 may be formed by patterning a layer comprised of their constituent material with lithography and etching processes. In an embodiment, the waveguide core 14 and the pad 20 of the photodetector 12 may be formed by patterning the semiconductor material, which may be single-crystal silicon, of the device layer of a silicon-on-insulator substrate. The

The semiconductor layer 22 of the photodetector 12 may be comprised of a light-absorbing material that is configured to absorb light of a given wavelength, such as a wavelength of light within an infrared wavelength band, and to generate charge carriers from photons of the absorbed light by photoelectric conversion. In an embodiment, the semiconductor layer 22 may be comprised of a different material from the waveguide core 14 and/or the pad 20. In an embodiment, the semiconductor layer 22 may be comprised of a material having a composition that includes germanium. In an embodiment, the semiconductor layer 22 may be comprised of intrinsic germanium. In an alternative embodiment, the semiconductor layer 22 may be comprised of a different light-absorbing material, such as a III-V compound semiconductor material, silicon-germanium, or silicon.

The semiconductor layer 22 may be formed by an epitaxial growth process. In an embodiment, the semiconductor layer 22 may be epitaxially grown inside a trench that is patterned in the pad 20 such that the semiconductor layer 22 includes a lower portion disposed below a top surface of the pad 20 and an upper portion disposed above the top surface of the pad 20. In an alternative embodiment, the semiconductor layer 22 may be formed on the top surface of the pad 20, instead of inside a trench, such that the semiconductor layer 22 is positioned fully above the top surface. In this regard, the semiconductor layer 22 may be epitaxially grown from the top surface of the pad 20 and then patterned by lithography and etching processes.

The photodetector 12 may include a doped region 40 and a doped region 42 that are formed in respective portions of the pad 20. The doped regions 40, 42, which may be characterized by different conductivity types, may extend through the entire thickness of the pad 20 to the underlying dielectric layer 16. The semiconductor layer 22 is laterally positioned on the pad 20 between the doped region 40 and the doped region 42. The doped region 40 and the doped region 42 may define an anode and a cathode of the photodetector 12.

The doped region 40 may be formed by, for example, ion implantation with an implantation mask having an opening that determines the implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 40. The implantation mask may be stripped after forming the doped region 40. In an embodiment, the semiconductor material of the doped region 40 may contain a p-type dopant, such as boron, that provides p-type electrical conductivity. In an alternative embodiment, a portion of the semiconductor layer 22 immediately adjacent to the doped region 40 and an underlying portion of the pad 20 may be implanted with the p-type dopant due to overlap of the opening in the implantation mask.

The doped region 42 may be formed by, for example, ion implantation with an implantation mask with an opening that determines an implanted area of the pad 20. The implantation mask may include a layer of photoresist applied by a spin-coating process, pre-baked, exposed to light projected through a photomask, baked after exposure, and developed with a chemical developer to define the opening over the area of the pad 20 to be implanted. The implantation conditions, such as ion species, dose, and kinetic energy, may be selected to tune the electrical and physical characteristics of the doped region 42. The implantation mask may be stripped after forming the doped region 42. In an embodiment, the semiconductor material of the doped region 42 may contain an n-type dopant, such as phosphorus, that provides n-type electrical conductivity. In an alternative embodiment, a portion of the semiconductor layer 22 immediately adjacent to the doped region 42 and an underlying portion of the pad 20 may be implanted with the n-type dopant due to overlap of the opening in the implantation mask.

A portion of the pad 20 overlapped by the semiconductor layer 22, and between the semiconductor layer 22 and the dielectric layer 16, may be comprised of intrinsic semiconductor material, such as intrinsic silicon, that is undoped by the ion implantations forming the doped regions 40, 42. The tapered portion of the waveguide core 14 may be aligned lengthwise with the intrinsic portion of the pad 20. In an embodiment, the intrinsic portion of the pad 20 may extend from the side edge 24 of the pad 20 to the side edge 25 of the pad 20. The doped region 40, the intrinsic semiconductor materials of the semiconductor layer 22 and the portion of the pad 20 beneath the semiconductor layer 22, and the doped region 42 may define a lateral p-i-n diode structure that enables the functionality of the photodetector 12.

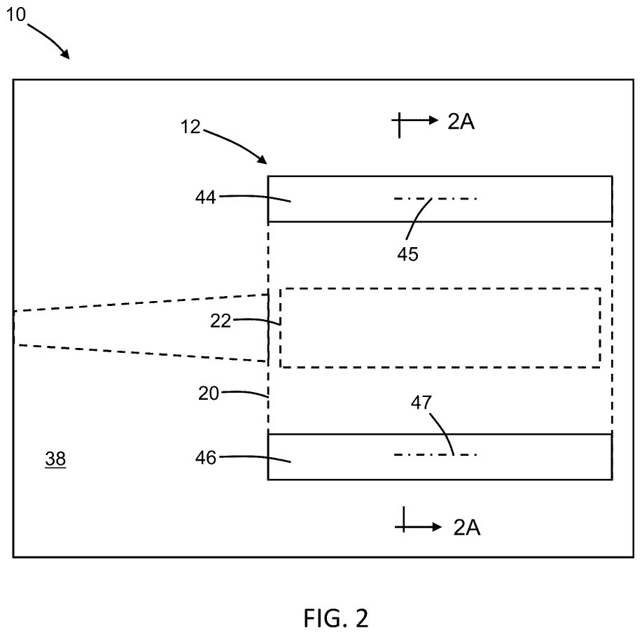

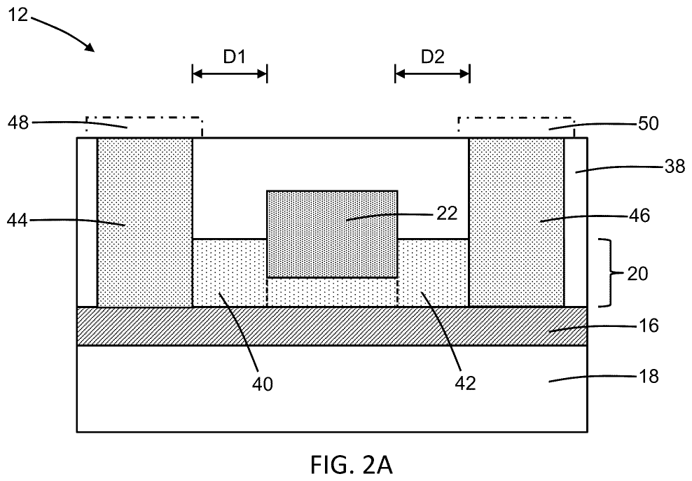

With reference to FIGS. 2, 2A in which like reference numerals refer to like features in FIGS. 1, 1A and at a subsequent fabrication stage, a dielectric layer 38 may be formed over the photodetector 12 and waveguide core 14. The dielectric layer 38 may be comprised of a dielectric material, such as silicon dioxide, having a refractive index that is less than the refractive index of the material constituting the waveguide core 14.

A metal layer 44 and a metal layer 46 may be formed that extend fully through the dielectric layer 38 and into respective portions of the pad 20. More specifically, the metal layer 44 may extend into a portion of the pad 20 that includes the doped region 40, and the metal layer 46 may extend into a portion of the pad 20 that includes the doped region 42. In an embodiment, the metal layers 44, 46 may penetrate fully through the respective portions of the pad 20 to the dielectric layer 16. The metal layers 44, 46 may be positioned in respective openings that are patterned in the dielectric layer 38 and the pad 20 by lithography and etching processes. The metal layer 44 may have a longitudinal axis 45, the metal layer 46 may have a longitudinal axis 47, and the longitudinal axes 45, 47 may be aligned parallel to the longitudinal axis 30 of the semiconductor layer 22.

The semiconductor layer 22 is laterally positioned between the metal layer 44 and the metal layer 46. The metal layer 44 is laterally positioned between the side edge 26 of the pad 20 and the sidewall 36 of the semiconductor layer 22. The metal layer 46 is laterally positioned between the side edge 27 of the pad 20 and the sidewall 37 of the semiconductor layer 22. A portion of the pad 20, which may include a residual portion of the doped region 40, is laterally positioned between the metal layer 44 and the portion of the pad 20 that includes the semiconductor layer 22. A portion of the pad 20, which may include a residual portion of the doped region 42, is laterally positioned between the metal layer 46 and the portion of the pad 20 that includes the semiconductor layer 22.

The position and dimensions of the metal layer 44, and the dimension D1 of the intervening portion of the pad 20 between the metal layer 44 and the semiconductor layer 22, are selected to provide a lateral offset of the metal layer 44 from the sidewall 36 toward the side edge 26. The position and dimensions of the metal layer 46, and the dimension D2 of the intervening portion of the pad 20 between the metal layer 46 and the semiconductor layer 22, are selected to provide a lateral offset of the metal layer 46 from the sidewall 37 toward the side edge 27. In an embodiment, the dimensions D1, D2 may be approximately equal to 0.15 multiplied by the wavelength of the light propagating in the waveguide core 14 to the photodetector 12.

The metal layers 44, 46 may be comprised of a metal, such as copper or aluminum, that is employed in back-end-of-line processing. In an alternative embodiment, the metal layers 44, 46 may be comprised of a noble metal, such as gold. Interconnects 48, 50 may be formed that are respectively coupled to the metal layers 44, 46, and may be used to bias the photodetector 12 and collect charge carriers.

In use, light propagates in the waveguide core 14 toward the photodetector 12 and is coupled from the waveguide core 14 to the semiconductor layer 22 of the photodetector 12. In an embodiment, the light received by the photodetector 12 may be laser light that is modulated as an optical signal. The semiconductor layer 22 of the photodetector 12 absorbs photons of the light and converts the absorbed photons into charge carriers by photoelectric conversion. The biasing of the doped regions 40, 42 causes the charge carriers to be collected and output through the metal layers 44, 46 to provide, as a function of time, a measurable photocurrent.

The photodetector 12 operates in a hybrid plasmonic mode due to the inclusion of the metal layers 44, 46. The electrical field in the operating photodetector 12 may be significantly enhanced due to the configuration featuring respective portions of the semiconductor material of the pad 20 between the metal layers 44, 46 and the semiconductor layer 22. The enhanced electric field may accelerate the transition of the charge carriers, which are represented by electron-hole pairs, generated by photoelectric conversion in the semiconductor layer 22 for collection and output from the photodetector 12. The photodetector 12 may be characterized by a high bandwidth, such as a bandwidth beyond sixty-five (65) gigahertz, that is desirable for high-speed photonic circuits and systems. The photodetector 12 may be characterized by lower loss, higher coupling efficiency, and improved responsivity in comparison with conventional plasmonic photodetectors. The metal layers 44, 46 may also assist with the optical confinement of the light in the photodetector 12.

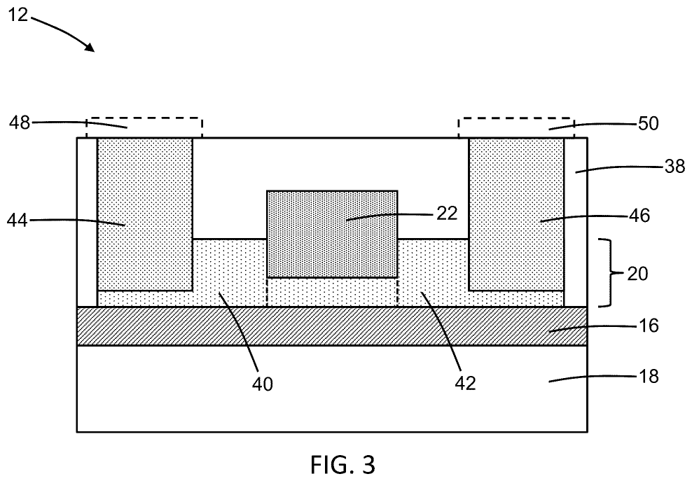

With reference to FIG. 3 and in accordance with alternative embodiments, the metal layers 44, 46 may only extend partially through the thickness of the pad 20 instead of penetrating fully through the pad 20. A portion of the pad 20, and more specifically, a portion of the doped region 40 is positioned between a bottom surface of the metal layer 44 and the dielectric layer 16. A portion of the pad 20, and more specifically, a portion of the doped region 42, is positioned between a bottom surface of the metal layer 44 and the dielectric layer 16.

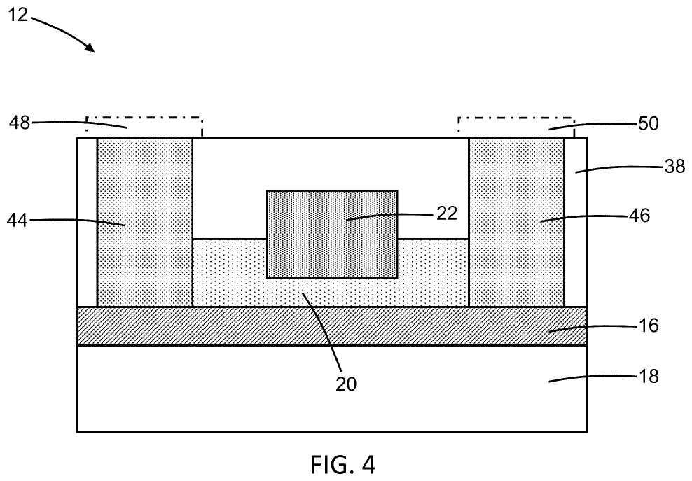

With reference to FIG. 4 and in accordance with alternative embodiments, the doped regions 40, 42 may be omitted from the pad 20 of the photodetector 12 such that the entire pad 20 is comprised of intrinsic semiconductor material that is undoped. The metal layers 44, 46 may penetrate either fully through the intrinsic semiconductor material of the pad 20 or partially through the intrinsic semiconductor material of the pad 20.

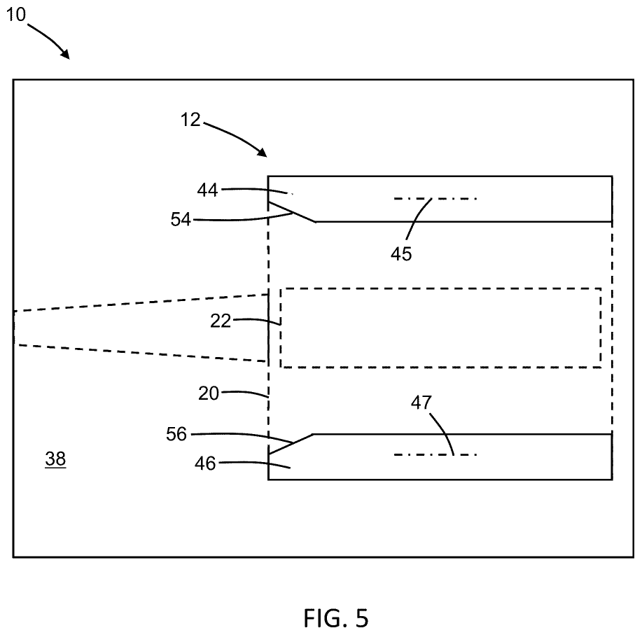

With reference to FIG. 5 and in accordance with alternative embodiments, the metal layer 44 may have a leading edge with a chamfered surface 54 arranged adjacent to the side edge 24 of the pad 20 and the sidewall 34 of the semiconductor layer 22. The metal layer 46 may also have a leading edge with a chamfered surface 56 arranged adjacent to the side edge 24 of the pad 20 and the sidewall 34 of the semiconductor layer 22. The chamfered surface 52 and the chamfered surface 54 may redirect reflected light to reduce optical return loss to the waveguide core 14.

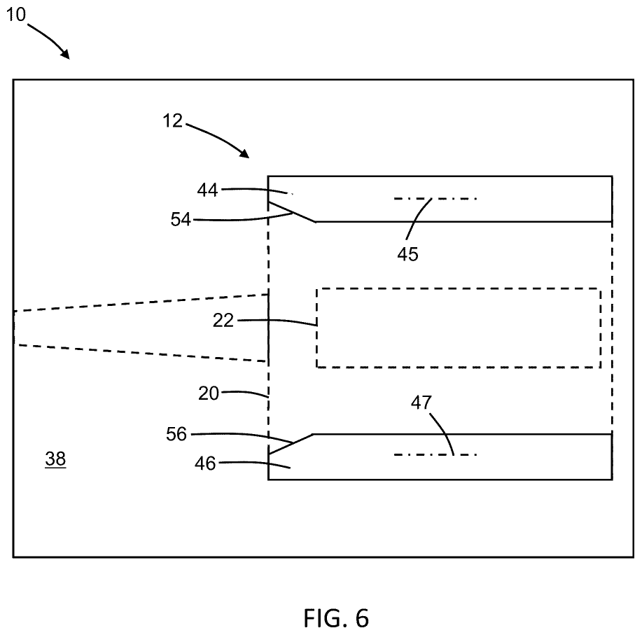

With reference to FIG. 6 and in accordance with alternative embodiments, the semiconductor layer 22 may be longitudinally offset relative to the chamfered surface 54 and the chamfered surface 56. To that end, the sidewall 34 of the semiconductor layer 22 may be shifted longitudinally away from the side edge 24 of the pad 20 such that the semiconductor layer 22 is absent in the space between the chamfered surface 54 and the chamfered surface 56.

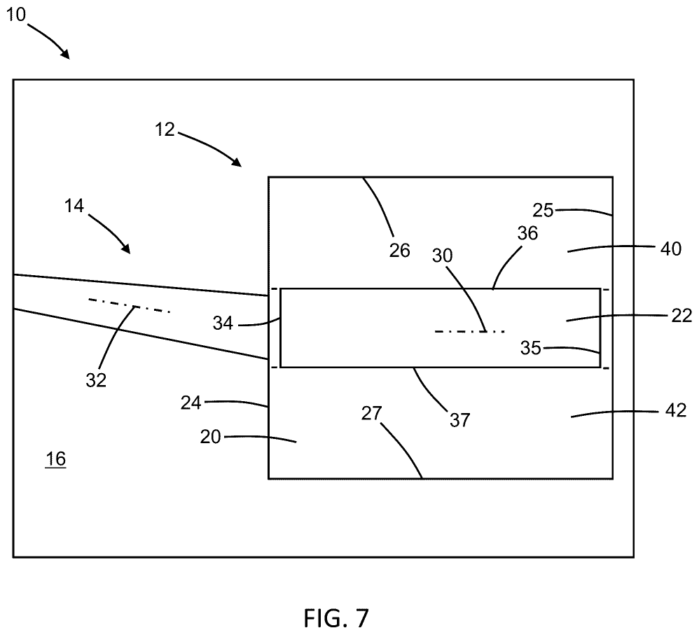

With reference to FIG. 7 and in accordance with alternative embodiments, the tapered portion of the waveguide core 14 adjoining the side edge 24 of the pad 20 may be slanted relative to the side edge 24 at an acute angle. More specifically, the longitudinal axis 32 of the tapered portion of the waveguide core 14 adjoining the side edge 24 may be slanted at the acute angle relative to the longitudinal axis 30 of the semiconductor layer 22. The slanting of the tapered portion of the waveguide core 14 may further reduce reflected light contributing to optical return loss to the waveguide core 14.

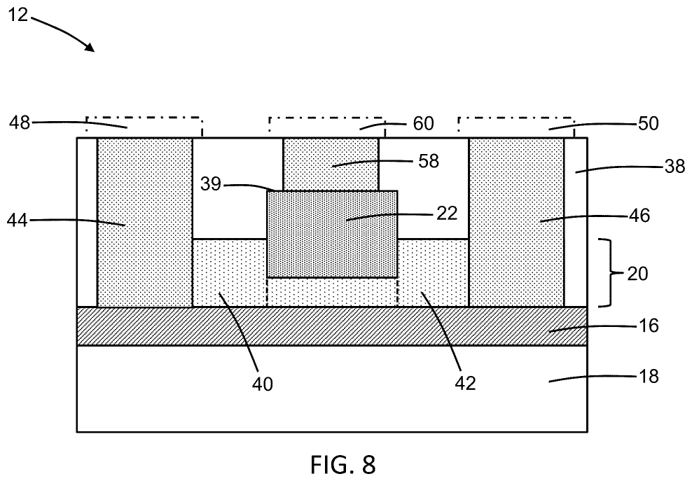

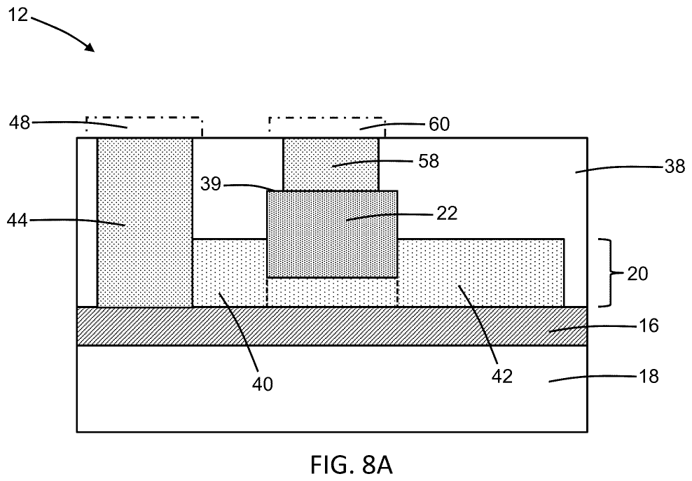

With reference to FIGS. 8, 8A and in accordance with alternative embodiments, the structure 10 may include a metal layer 58 that extends through the dielectric layer 38 to a top surface 39 of the semiconductor layer 22. The top surface 39 of the semiconductor layer 22 is surrounded at its perimeter by the sidewalls 34, 35, 36, 37. The metal layer 58 may be similar or identical to the metal layers 44, 46. The metal layer 58 may be disposed in an opening that is patterned in the dielectric layer 38 by lithography and etching processes. An interconnect 60, which is similar or identical to interconnects 48, 50, may be formed that is coupled to the metal layer 58.

The metal layer 58 may have a directly contacting relationship with the top surface 39 of the semiconductor layer 22. In an alternative embodiment, the metal layers 44, 46 may extend partially through the pad 20 instead of penetrating fully through the pad 20. In an alternative embodiment, the metal layer 46 may be omitted from the photodetector 12 as shown in FIG. 8A. In an alternative embodiment, the doped regions 40, 42 may be omitted from the pad 20 of the photodetector 12 such that the pad 20 is comprised of intrinsic semiconductor material.

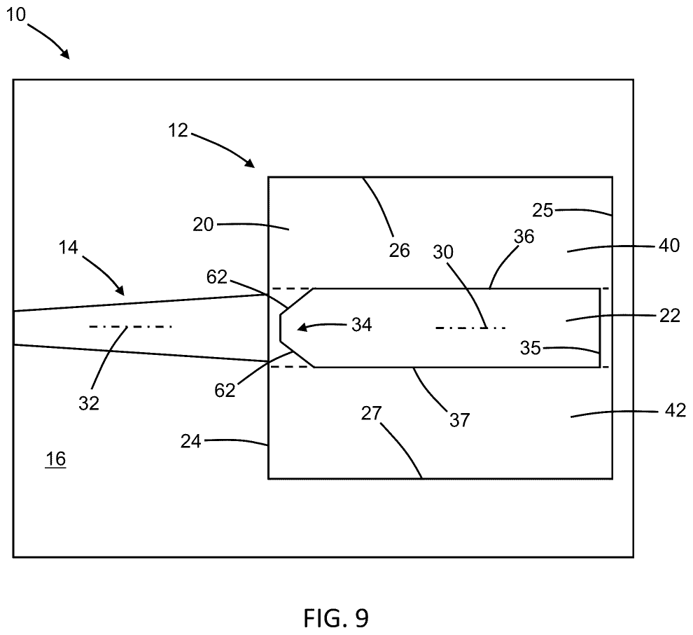

With reference to FIG. 9 and in accordance with alternative embodiments, the sidewall 34 of the semiconductor layer 22 may include chamfered surfaces 62 that are arranged adjacent to the side edge 24 of the pad 20 and the tapered portion of the waveguide core 14 adjoining the side edge 24 of the pad 20. The metal layers 44, 46 are subsequently formed that penetrate either fully through the semiconductor material of the pad 20 or partially through the semiconductor material of the pad 20. In alternative embodiments, the chamfered surfaces 62 may have a different arrangement, such as an arrangement that provides a concavity instead of a convexity. The chamfered surfaces 62 of the sidewall 34 of the semiconductor layer 22 may further reduce reflected light contributing to optical return loss to the waveguide core 14.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/−10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a photonic chip, the structure comprising:
a photodetector including a pad, a semiconductor layer on the pad, and a first metal layer that extends into the pad, the semiconductor layer configured to absorb light of a given wavelength.

2. The structure of claim 1 further comprising:
a waveguide core including a portion adjoined to the pad, the portion of the waveguide core adjacent to the semiconductor layer.

3. The structure of claim 2 wherein the waveguide core adjoins a side edge of the pad, and the waveguide core has a longitudinal axis that is slanted at an acute angle relative to the side edge of the pad.

4. The structure of claim 2 wherein the waveguide core adjoins a side edge of the pad, and the first metal layer includes a chamfered surface adjacent to the side edge of the pad and the waveguide core.

5. The structure of claim 1 wherein the photodetector includes a second metal layer that extends into the pad, and the semiconductor layer is laterally positioned between the first metal layer and the second metal layer.

6. The structure of claim 5 wherein the pad includes a first doped region and a second doped region, the first doped region has a first conductivity type, the second doped region has a second conductivity type different from the first conductivity type, and the semiconductor layer is laterally positioned between the first doped region and the second doped region.

7. The structure of claim 5 wherein the pad comprises a semiconductor material, and the pad includes a first portion laterally between the first metal layer and the semiconductor layer, and the pad includes a second portion laterally between the second metal layer and the semiconductor layer.

8. The structure of claim 1 wherein the first metal layer comprises copper or aluminum, and the semiconductor layer comprises germanium.

9. The structure of claim 1 wherein the first metal layer extends partially through the pad.

10. The structure of claim 1 wherein the first metal layer extends fully through the pad.

11. The structure of claim 10 further comprising:
a silicon-on-insulator substrate including a semiconductor substrate and a first dielectric layer on the semiconductor substrate,
wherein the pad is positioned on the first dielectric layer, and the first metal layer extends fully through the pad to the first dielectric layer.

12. The structure of claim 1 wherein the photodetector includes a second metal layer that is positioned on the semiconductor layer.

13. The structure of claim 12 wherein the photodetector includes a third metal layer that extends into the pad, and the semiconductor layer and the second metal layer are laterally positioned between the first metal layer and the third metal layer.

14. The structure of claim 12 wherein the semiconductor layer has a top surface, and the second metal layer directly contacts the top surface of the semiconductor layer.

15. The structure of claim 12 further comprising:
a silicon-on-insulator substrate including a semiconductor substrate and a first dielectric layer on the semiconductor substrate,
wherein the semiconductor layer is positioned between the second metal layer and the first dielectric layer.

16. The structure of claim 1 further comprising:
a silicon-on-insulator substrate including a semiconductor substrate and a first dielectric layer on the semiconductor substrate; and
a second dielectric layer on the first dielectric layer, the pad, and the semiconductor layer,
wherein the first metal layer extends through the second dielectric layer.

17. The structure of claim 1 wherein the pad includes a portion laterally between the first metal layer and the semiconductor layer.

18. The structure of claim 17 wherein the portion of the pad comprises an intrinsic semiconductor material.

19. The structure of claim 17 wherein the portion of the pad comprises a doped semiconductor material.

20. A method of forming a structure for a photonic chip, the method comprising:
forming a pad of a photodetector;
forming a semiconductor layer on the pad, wherein the semiconductor layer is configured to absorb light of a given wavelength; and
forming a metal layer that extends into the pad.
